(19) United States
(12) Patent Application Publication
(10) Pub. No.: US 2002/0058410 A1
(43) Pub. Date: May 16, 2002

(54) Method of prohibiting from producing protrusion alongside silicide layer of gate

(75) Inventors: Ben Sung, Hsinchu (TW); Heng-Kai Hsu, Hsinchu (TW)

Correspondence Address: Dike, Bronstein, Roberts & Cushman, In Edwards & Angell, LLP, 130 Water Street, Boston, MA, 02109-4280, US

(73) Assignee: ProMOS Technologies, Inc., Hsinchu (TW)

(21) Appl. No.: 09/817,934

(22) Filed: Mar. 27, 2001

(30) Foreign Application Priority Data
Nov. 16, 2000 (TW) 89124304

(51) Int. Cl. H01L 21/336; H01L 21/4763; H01L 21/44

(52) U.S. Cl. 438/649; 438/655

(57) ABSTRACT

A method of prohibiting from producing a protrusion alongside a silicide layer of a gate unit is disclosed. The method includes steps of (a) providing a chamber and a semiconductor wafer having the gate unit thereon, (b) loading the semiconductor wafer into the chamber, (c) providing a mixing gas of nitrogen gas and hydrogen gas into the chamber and performing a rapid thermal anneal (RTA) step for the gate unit, and (d) performing a rapid thermal oxidation (RTO) step for the gate unit. Alternatively, the method includes steps of (a) providing a first chamber and a semiconductor wafer having a gate unit thereon, (b) loading the semiconductor wafer into the first chamber and purging oxygen gas therein, (c) performing a rapid thermal anneal (RTA) step for the gate unit, and (d) performing a rapid thermal oxidation (RTO) step for the gate unit.

### FIELD OF THE INVENTION

The present invention is related to a method of prohibiting from producing a protrusion alongside a silicide layer, and more particularly to a method of prohibiting from producing a protrusion alongside a silicide layer of a gate unit.

### BACKGROUND OF THE INVENTION

It's well known that the quality of a metal-oxide-semiconductor field effect transistor (MOSFET) is related to the yield and performance of a semiconductor product.

First of all, please refer to FIGS. 1 (a)˜(g) schematically showing a method of forming a metal-oxide-semiconductor field effect transistor (MOSFET) according to the prior art. This method is described in detail as follows.

As shown in FIG. 1 (a), a gate oxide layer 11 is formed on a silicon substrate 10 by a thermal oxidation step.

In FIG. 1 (b), a polysilicon layer 12 is formed on the gate oxide layer 11 by a chemical vapor deposition (CVD) technique. Thereafter, for lowing the resistivity of the polysilicon layer 12, impurities such as phosphorus ions and arsenic ions are doped thereinto by a thermal diffusion step or an ion implantation step.

In FIG. 1 (c), a tungsten silicide layer 13 and a silicon nitride layer 14 are then formed on the polysilicon layer 12 by a chemical vapor deposition (CVD) technique.

In FIG. 1 (d), the silicon nitride layer 14 is patterned by a photolithography technique and a wet etching technique for defining a gate region 141.

In FIG. 1 (e), after a dry etching step by using the silicon nitride region 141 as a mask layer, a gate unit 16 is formed. The gate unit 16 includes a silicon nitride layer 14, a tungsten silicide layer 13, a polysilicon layer 12 and a gate oxide layer 11.

In FIG. 1 (f), for lowing the resistivity of the tungsten silicide layer 13 and recovering the damaged gate unit 16 and the silicon substrate 10 incurred by the preceding dry etching step in FIG. 1 (e), a rapid thermal anneal (RTA) step is performed first by providing a nitrogen gas in the chamber. Then, for rounding the gate oxide layer 11 to prevent the breakdown voltage of the gate unit 16 from being lowered, a rapid thermal oxidation (RTO) step is performed by providing a oxygen gas in the same chamber to form a thermal oxide layer 15 around the gate unit 16. Because of the thermal oxidation (RTO) step, the gate oxide layer 11 is rounded and a leakage current will not happen, and thus the breakdown voltage of the gate unit will not be lowered.

As shown in FIG. 1 (g), a spacer 17, a source 18 and a drain 19 is formed in the end for completely forming the metal-oxide-semiconductor field effect transistor (MOSFET).

However, the method of forming a metal-oxide-semiconductor field effect transistor (MOSFET) according to the prior art has a serious disadvantage described as follows. As described above in FIG. 1 (f), because the rapid thermal anneal (RTA) and rapid thermal oxidation (RTO) steps are performed in the same chamber, a protrusion 21 would be produced alongside the tungsten silicide layer 13 (as shown in FIG. 2(a) which is a SEM diagram schematically showing a cross-sectional view of a gate unit 16 formed according to the prior art and FIG. 2(b) which is a SEM diagram schematically showing a top view of a gate unit 16 formed according to the prior art). The protrusion 21 is produced alongside the tungsten silicide layer 13 during the present rapid thermal anneal (RTA) and rapid thermal oxidation (RTO) steps because of that the oxygen gas is remained after the preceding rapid thermal oxidation (RTO) steps are completely performed in the same chamber. The protrusion 21 is composed of the oxide of tungsten and the silicon oxide. Once the protrusion 21 is formed, the yield of the manufactured semiconductor product is significantly lowered.

Accordingly, it is attempted by the present applicant to solve the above-described problems encountered in the prior arts.

### SUMMARY OF THE INVENTION

An object of the present invention is to provide a method of prohibiting from producing a protrusion alongside a silicide layer of a gate unit.

Another object of the present invention is to provide a method of improving the yield of the semiconductor products.

A further object of the present invention is to provide a method of improving the quality and performance of the semiconductor products.

According to one aspect of the present invention, a method of prohibiting from producing a protrusion alongside a silicide layer of a gate unit is provided. The method includes steps of (a) providing a chamber and a semiconductor wafer having the gate unit thereon, (b) loading the semiconductor wafer into the chamber, (c) providing a mixing gas of nitrogen gas and hydrogen gas into the chamber and performing a rapid thermal anneal (RTA) step for the gate unit, and (d) performing a rapid thermal oxidation (RTO) step for the gate unit.

Preferably, the semiconductor wafer is a silicon wafer.

Preferably, the silicide layer is a tungsten silicide layer.

Preferably, the gate unit includes a gate oxide layer, a polysilicon layer and the tungsten silicide layer.

Preferably, the gate unit further includes a silicon nitride layer.

Preferably, the concentration of the hydrogen gas in the mixing gas is ranged from 5 to 50%.

Preferably, the rapid thermal anneal (RTA) step is performed at a temperature ranged from 700 to 950° C.

Preferably, the rapid thermal anneal (RTA) step is performed for a period of time ranged from 0.5 to 4 minutes.

Preferably, the rapid thermal oxidation (RTO) step is performed at a temperature ranged from 950 to 1200° C.

Preferably, the rapid thermal oxidation (RTO) step is performed for a period of time ranged from 1 to 5 minutes.

According to another aspect of the present invention, a process of manufacturing a gate is provided. The process includes steps of (a) providing a semiconductor wafer, (b) forming a gate oxide layer on the semiconductor wafer, (c) forming a polysilicon layer on the gate oxide layer, (d) forming a silicide layer on the polysilicon layer, (e) patterning the silicide layer, the polysilicon layer and the gate oxide layer for forming a gate unit on the semiconductor wafer, (f) providing a mixing gas of nitrogen gas and hydrogen gas into the chamber and performing a rapid thermal anneal (RTA) step for the gate unit, and (g) performing a rapid thermal oxidation (RTO) step for the gate unit.

Preferably, the step (c) further includes a step of (c1) doping VA ions into the polysilicon layer by an ion implantation technique.

Preferably, the step (e) includes steps of (e1) forming a mask layer on the silicide layer, (e2) defining an area of the gate unit by a photolithography technique, and (e3) performing a dry etching step to remove portions of the silicide layer, the polysilicon layer and the gate oxide layer for forming the gate unit.

Preferably, the mask layer is a silicon nitride layer.

Preferably, the concentration of the hydrogen gas in the mixing gas is ranged from 5 to 50%.

Preferably, the rapid thermal anneal (RTA) step is performed at a temperature ranged from 700 to 950° C.

Preferably, the rapid thermal anneal (RTA) step is performed for a period of time ranged from 0.5 to 4 minutes.

According to further another aspect of the present invention, a method of prohibiting from producing a protrusion alongside a silicide layer of a gate is provided. The method includes steps of (a) providing a first chamber and a semiconductor wafer having a gate unit thereon, (b) loading the semiconductor wafer into the first chamber and purging oxygen gas therein, (c) performing a rapid thermal anneal (RTA) step for the gate unit, and (d) performing a rapid thermal oxidation (RTO) step for the gate unit.

Preferably, the semiconductor wafer is a silicon wafer.

Preferably, the silicide layer is a tungsten silicide layer.

Preferably, the gate unit includes a gate oxide layer, a polysilicon layer and the tungsten silicide layer.

Preferably, the gate unit further includes a silicon nitride layer.

Preferably, the step of purging oxygen gas is performed by inputting a nitrogen gas into the first chamber.

Preferably, the step of purging oxygen gas is performed by vacuuming the first chamber.

Preferably, the step of purging oxygen gas is performed until a extent of a concentration of the oxygen gas is lower than 500 ppm.

Preferably, the first chamber is a chamber of loading one semiconductor wafer at one time.

Preferably, the first chamber is a chamber of loading plural semiconductor wafers at one time.

Preferably, after the step (c) further includes steps of (c1) providing a second chamber, and (c2) loading the semiconductor wafer into the second chamber.

Preferably, the rapid thermal oxidation (RTO) step is performed in the second chamber.

### BRIEF DESCRIPTION OF THE DRAWING

The present invention may best be understood through the following description with reference to the accompanying drawings, in which:

FIGS. 1 (a)˜(g) schematically shows a method of forming a metaloxide-semiconductor field effect transistor (MOSFET) according to the prior art;

FIG. 2(a) is a SEM diagram schematically showing a cross-sectional view of a gate unit formed according to the prior art;

FIG. 2(b) is a SEM diagram schematically showing a top view of a gate unit formed according to the prior art;

FIG. 3 is a schematic diagram showing how a hydrogen gas film stabilize the sidewalls of a gate unit; and

FIG. 4 is a SEM diagram schematically showing a top view of a gate unit formed according to the present invention.

### DETAILED DESCRIPTION OF THE PREFERRED EMBODIMENTS

As described above, a protrusion might be produced alongside the tungsten silicide layer of a gate unit during the rapid thermal anneal (RTA) and rapid thermal oxidation (RTO) steps. According to the present invention, the protrusion would not be produced and the yield of the semiconductor products would not be lowered. The present invention may best be understood through the following description.

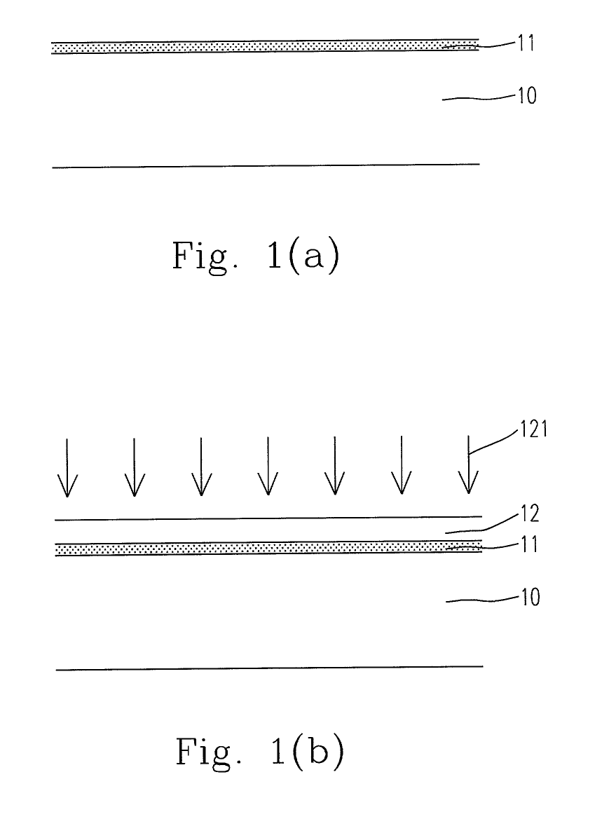

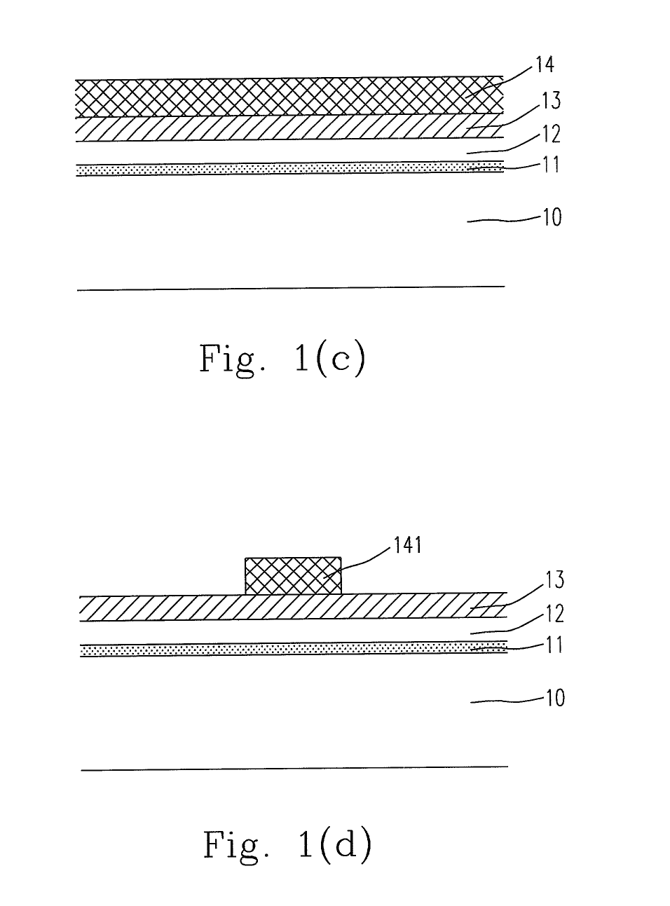

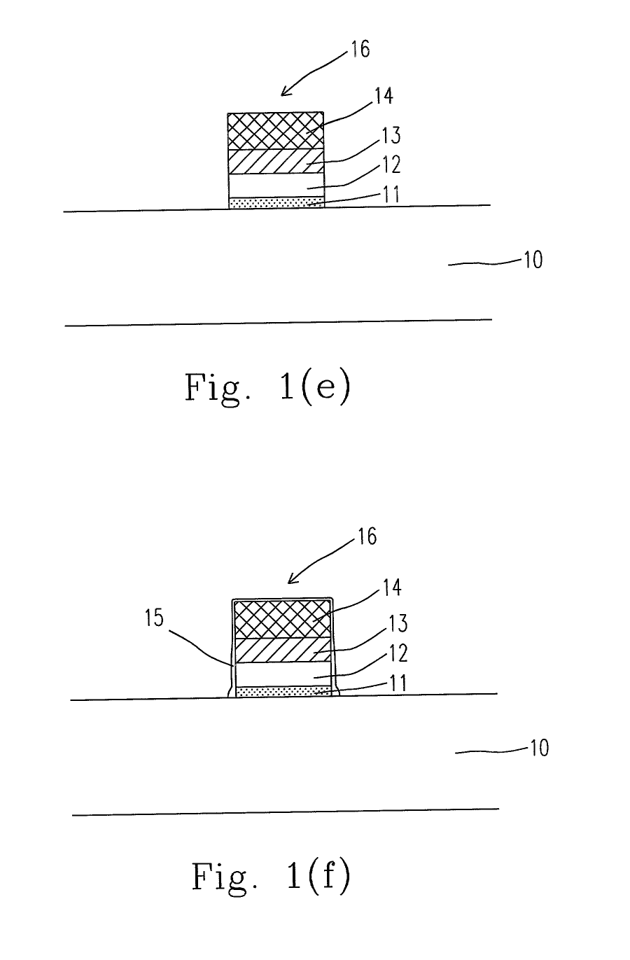

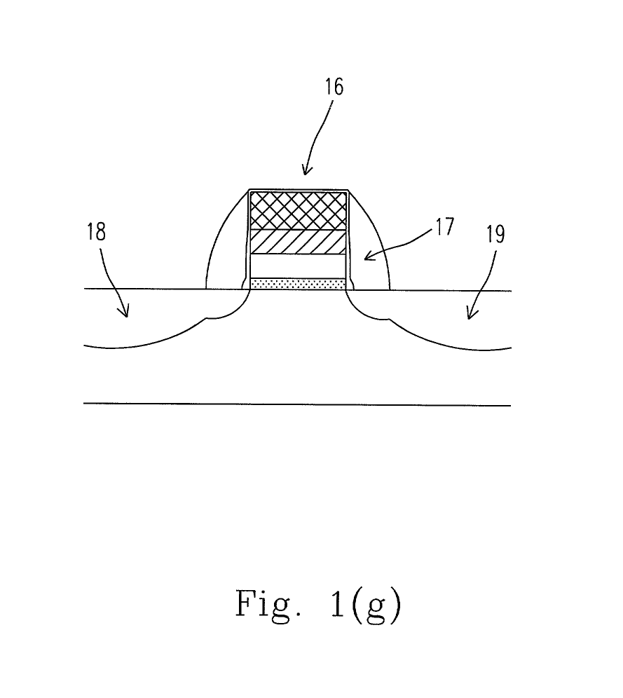

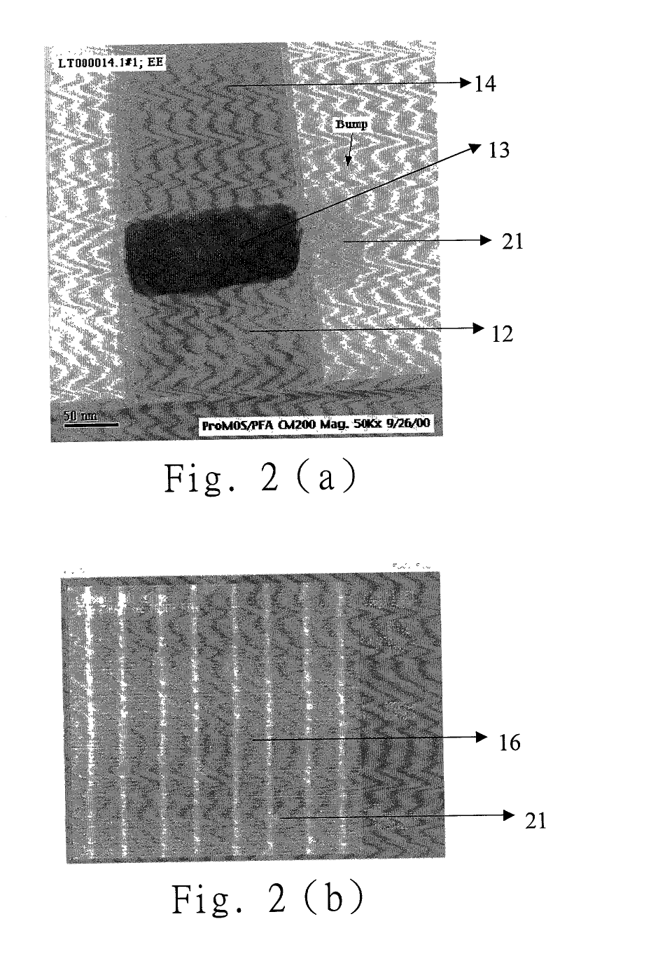

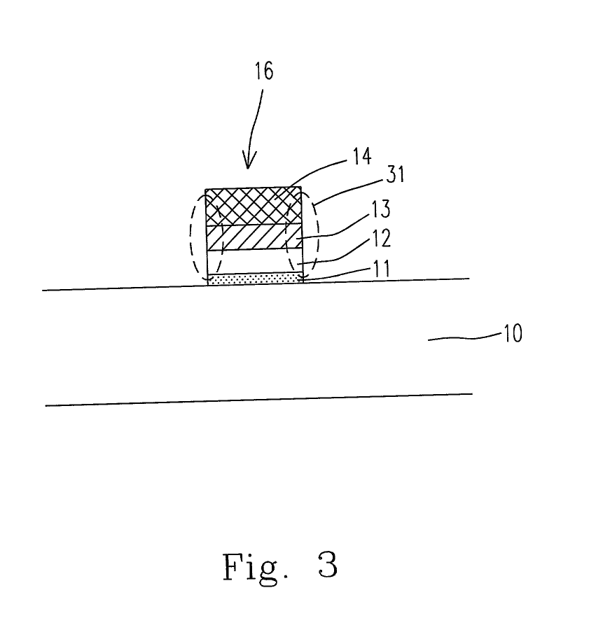

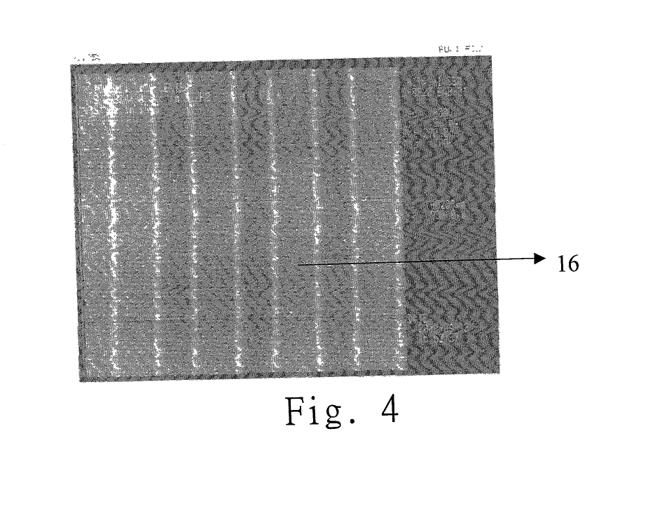

In FIG. 1(f), according to the present invention, a rapid thermal anneal (RTA) step is performed first by providing a mixing gas of nitrogen gas and hydrogen gas. The concentration of the hydrogen gas in the mixing gas is ranged from 5 to 50%. Preferably, the concentration of the hydrogen gas in the mixing gas is 10%. The rapid thermal anneal (RTA) step is performed at a temperature ranged from 700 to 950° C. for a period of time ranged from 0.5 to 4 minutes. Preferably, the rapid thermal anneal (RTA) step is performed for 1 minute. Then, a rapid thermal oxidation (RTO) step is performed by providing a oxygen gas in the same chamber to form a thermal oxide layer around the gate unit. The rapid thermal oxidation (RTO) step is performed at a temperature ranged from 950 to 1200° C. for a period of time ranged from 1 to 5 minutes. Preferably, the rapid thermal oxidation (RTO) step is performed at 1080° C. for 2.5 minutes. Please refer to FIG. 3 which is a schematic diagram showing how a hydrogen gas film 31 stabilize the sidewalls of a gate unit 16. In spite of that the oxygen gas might be remained after the preceding rapid thermal oxidation (RTO) steps are completely performed in the same chamber, a hydrogen gas film 31 formed around the gate unit 16 during the present rapid thermal anneal (RTA) step by providing a mixing gas of nitrogen gas and hydrogen gas will stable the sidewalls of a gate unit 16 such that a protrusion would not be produced alongside the silicide layer of the gate unit 16. FIG. 4 is a SEM diagram schematically showing a top view of a gate unit 16 formed according to the present invention, wherein there are no protrusions formed therein.

Alternatively, before the rapid thermal anneal (RTA) step is performed, the oxygen gas in the chamber is purged first until the concentration of the oxygen gas is lower than 500 ppm. The step of purging oxygen gas can be performed by inputting a nitrogen gas into the chamber or vacuuming the chamber. The rapid thermal anneal (RTA) and rapid thermal oxidation (RTO) steps are performed thereafter. Because the oxygen gas is purged in advance, a protrusion would not be produced alongside the silicide layer of the gate unit during the rapid thermal anneal (RTA) and rapid thermal oxidation (RTO) steps. Certainly, for further prohibiting from producing a protrusion alongside a silicide layer of a gate unit, the rapid thermal oxidation (RTO) step can be performed in another chamber which differs from that the rapid thermal anneal (RTA) step is performed in.

The present invention is directed to a method of prohibiting from producing a protrusion alongside a silicide layer of a gate unit. According to the present invention, no matter whether the chamber is a chamber of loading one semiconductor wafer at one time or a chamber of loading plural semiconductor wafers at one time, the problems encountered in the prior arts are solved. The present invention possesses inventive step, and it's unobvious for one skilled in the art to develop the present invention.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A method of prohibiting from producing a protrusion alongside a silicide layer of a gate unit, comprising steps of:
(a) providing a chamber and a semiconductor wafer having said gate unit thereon;
(b) loading said semiconductor wafer into said chamber;
(c) providing a mixing gas of nitrogen gas and hydrogen gas into said chamber and performing a rapid thermal anneal (RTA) step for said gate unit; and
(d) performing a rapid thermal oxidation (RTO) step for said gate unit.

2. The method according to claim 1, wherein said semiconductor wafer is a silicon wafer, and said silicide layer is a tungsten silicide layer.

3. The method according to claim 1, wherein said gate unit comprises a gate oxide layer, a polysilicon layer, a silicon nitride layer and a silicide layer.

4. The method according to claim 1, wherein the concentration of said hydrogen gas in said mixing gas is ranged from 5 to 50%.

5. The method according to claim 1, wherein said rapid thermal anneal (RTA) step is performed at a temperature ranged from 700 to 950° C.

6. The method according to claim 5, wherein said rapid thermal anneal (RTA) step is performed for a period of time ranged from 0.5 to 4 minutes.

7. The method according to claim 1, wherein said rapid thermal oxidation (RTO) step is performed at a temperature ranged from 950 to 1200° C.

8. The method according to claim 7, wherein said rapid thermal oxidation (RTO) step is performed for a period of time ranged from 1 to 5 minutes.

9. A process of manufacturing a gate, comprising steps of:
(a) providing a semiconductor wafer;
(b) forming a gate oxide layer on said semiconductor wafer;
(c) forming a polysilicon layer on said gate oxide layer;
(d) forming a silicide layer on said polysilicon layer;
(e) patterning said silicide layer, said polysilicon layer and said gate oxide layer for forming a gate unit on said semiconductor wafer;
(f) providing a mixing gas of nitrogen gas and hydrogen gas into said chamber and performing a rapid thermal anneal (RTA) step for said gate unit; and
(g) performing a rapid thermal oxidation (RTO) step for said gate unit.

10. The process according to claim 9, wherein said step (c) further comprises a step of (c1) doping VA ions into said polysilicon layer by an ion implantation technique.

11. The process according to claim 9, wherein said step (e) comprises steps of:
(e1) forming a mask layer on said silicide layer, wherein said mask layer is a silicon nitride layer;
(e2) defining an area of said gate unit by a photolithography technique; and
(e3) performing a dry etching step to remove portions of said silicide layer, said polysilicon layer and said gate oxide layer for forming said gate unit.

12. The process according to claim 9, wherein the concentration of said hydrogen gas in said mixing gas is ranged from 5 to 50%.

13. The process according to claim 9, wherein said rapid thermal anneal (RTA) step is performed at a temperature ranged from 700 to 950° C. for a period of time ranged from 0.5 to 4 minutes.

14. A method of prohibiting from producing a protrusion alongside a silicide layer of a gate, comprising steps of:
(a) providing a first chamber and a semiconductor wafer having a gate unit thereon;
(b) loading said semiconductor wafer into said first chamber and purging oxygen gas therein;
(c) performing a rapid thermal anneal (RTA) step for said gate unit; and
(d) performing a rapid thermal oxidation (RTO) step for said gate unit.

15. The method according to claim 14, wherein said step of purging oxygen gas is perform ed by inputting a nitrogen gas into said first chamber.

16. The method according to claim 14, wherein said step of purging oxygen gas is performed until an extent of a concentration of said oxygen gas is lower than 500 ppm.

17. The method according to claim 14, wherein said first chamber is a chamber of loading one semiconductor wafer at one time.

18. The method according to claim 14, wherein said first chamber is a chamber of loading plural semiconductor wafers at one time.

19. The method according to claim 14, wherein after said step (c) further comprises steps of:
(c1) providing a second chamber; and
(c2) loading said semiconductor wafer into said second chamber.

20. The method according to claim 19, wherein said rapid thermal oxidation (RTO) step is performed in said second chamber.
